(19) United States
(12) Patent Application Publication
(10) Pub. No.: US 2025/0294872 A1
(43) Pub. Date: Sep. 18, 2025

(54) BOTTOM CONTACT FOR STACKED FIELD-EFFECT TRANSISTOR (FET)

(71) Applicant: International Business Machines Corporation, Armonk, NY (US)

(72) Inventors: Chanro Park, Clifton Park, NY (US); Ruilong Xie, Niskayuna, NY (US); Juntao Li, Cohoes, NY (US); Julien Frougier, Albany, NY (US); Min Gyu Sung, Latham, NY (US)

(21) Appl. No.: 18/605,896

(22) Filed: Mar. 15, 2024

(51) Int. Cl. H01L 27/092; H01L 21/822; H01L 21/8238; H01L 29/06; H01L 29/08; H01L 29/417; H01L 29/423; H01L 29/66; H01L 29/775

(52) U.S. Cl. CPC H10D 84/856; H10D 30/014; H10D 30/43; H10D 30/6729; H10D 30/6735; H10D 62/121; H10D 62/151; H10D 84/017; H10D 84/0186; H10D 84/038; H10D 88/01

(57) ABSTRACT

Embodiments of the invention include a method for fabricating a semiconductor device and the resulting structure. A first source/drain region for a first field effect transistor (FET) is formed. A dielectric liner is formed. An interlayer dielectric (ILD) is formed. A second source/drain region for a second FET is formed. The ILD and the dielectric liner are each recessed to expose a top surface of the first source/drain region. A second dielectric liner is formed. A second ILD is formed. A trench is formed through the second ILD above the first source/drain region. An exposed portion of the dielectric liner within the trench is removed. A first contact is formed in the trench.

### BACKGROUND

The present invention relates generally to the field of semiconductor devices and fabrication, and more particularly to stacked integrated circuit structures, containing field-effect transistors (FETs).

The use of non-planar semiconductor devices such as, for example, semiconductor fin field effect transistors (FinFETs) is the next step in the evolution of complementary metal oxide semiconductor (CMOS) devices. One type of non-planar semiconductor device that has been touted as a viable option beyond the 7 nm technology node is a nanosheet containing device. By “nanosheet containing device” it is meant that the device contains one or more layers of semiconductor channel material portions having a vertical thickness that is substantially less than its width.

Nanosheet formation relies on the selective removal of one semiconductor material (e.g., silicon) to another semiconductor material (e.g., a germanium alloy) to form suspended nanosheets for gate-all-around devices. Source/drain (S/D) regions for nanosheet containing devices are currently formed by epitaxial growth of a semiconductor material upwards from an exposed surface of the semiconductor substrate and from sidewalls of each nanosheet.

A stacked device is formed by stacking one FET over another FET, greatly reducing the footprint of the device and increase the transistor density.

### SUMMARY

Embodiments of the invention include a semiconductor structure that includes a first transistor having a first source/drain region. The structure further includes a second transistor, where the second transistor is stacked above the first transistor. The structure further includes a first dielectric liner between a first interlayer dielectric (ILD) and a second ILD, where the first dielectric liner is below a top surface of the first source/drain region.

Embodiments of the invention include a semiconductor structure that includes a bottom source/drain region. The structure further includes a top source/drain region. The structure further includes a dielectric liner between a bottom ILD and a top ILD, where the dielectric liner is below a top surface of the bottom source/drain region.

Embodiments of the invention include a method for fabricating a semiconductor device. The method includes forming a first source/drain region for a first field effect transistor (FET). The method can also include forming a dielectric liner. The method can also include forming an ILD. The method can also include forming a second source/drain region for a second FET. The method can also include recessing the ILD and the dielectric liner to expose a top surface of the first source/drain region. The method can also include forming a second dielectric liner. The method can also include forming a second ILD. The method can also include forming a trench through the second ILD above the first source/drain region. The method can also include removing an exposed portion of the dielectric liner within the trench. The method can also include forming a first contact in the trench.

### BRIEF DESCRIPTION OF THE DRAWINGS

FIG. 1 depicts a simplified top-down view of a device during the method of forming the device, the device including a bottom active device area (RX), top RX, gates, and bottom source/drain contact of each stacked FET structure, in accordance with an embodiment of the invention.

FIG. 2A depicts a cross-sectional view, along section line A of FIG. 1, and FIG. 2B depicts a cross-sectional view, along section line B of FIG. 1, of a process of the device during the method of forming the device subsequent to nanosheet stack patterning, shallow trench isolation (STI) formation, dummy gate formation, silicon germanium (SiGe) removal, middle dielectric isolation, nanosheet recessing, inner spacer formation, bottom source/drain formation, poly open chemical-mechanical planarization (POC) liner deposition, oxide fill, oxide recess, and exposed POC liner removal, in accordance with an embodiment of the invention.

FIG. 3A depicts a cross-sectional view, along section line A of FIG. 1, and FIG. 3B depicts a cross-sectional view, along section line B of FIG. 1, of a process of forming a top source/drain region, in accordance with an embodiment of the invention.

FIG. 4A depicts a cross-sectional view, along section line A of FIG. 1, and FIG. 4B depicts a cross-sectional view, along section line B of FIG. 1, of a process of removing additional interlayer dielectric (ILD) material, in accordance with an embodiment of the invention.

FIG. 5A depicts a cross-sectional view, along section line A of FIG. 1, and FIG. 5B depicts a cross-sectional view, along section line B of FIG. 1, of a process of removing exposed portions of the POC liner, in accordance with an embodiment of the invention.

FIG. 6A depicts a cross-sectional view, along section line A of FIG. 1, and FIG. 6B depicts a cross-sectional view, along section line B of FIG. 1, of a process of forming additional POC liner material and ILD material, in accordance with an embodiment of the invention.

FIG. 7A depicts a cross-sectional view, along section line A of FIG. 1, and FIG. 7B depicts a cross-sectional view, along section line B of FIG. 1, of a process of removing a sacrificial gate portion and a sacrificial semiconductor material layer, and the formation of a replacement gate and a sacrificial cap, in accordance with an embodiment of the invention.

FIG. 8A depicts a cross-sectional view, along section line A of FIG. 1, and FIG. 8B depicts a cross-sectional view, along section line B of FIG. 1, of a process of forming additional ILD material, in accordance with an embodiment of the invention.

FIG. 9A depicts a cross-sectional view, along section line A of FIG. 1, and FIG. 9B depicts a cross-sectional view, along section line B of FIG. 1, of an initial step in the process of forming a source/drain contact trench for the bottom source/drain region, in accordance with an embodiment of the invention.

FIG. 10A depicts a cross-sectional view, along section line A of FIG. 1, and FIG. 10B depicts a cross-sectional view, along section line B of FIG. 1, of an initial step in the process of forming a source/drain contact trench for the top source/drain region, in accordance with an embodiment of the invention.

FIG. 11A depicts a cross-sectional view, along section line A of FIG. 1, and FIG. 11B depicts a cross-sectional view, along section line B of FIG. 1, of a process of removing horizontal portions of POC liner 230, exposing top surfaces of the top source/drain region and the bottom source/drain region, in accordance with an embodiment of the invention.

FIG. 12A depicts a cross-sectional view, along section line A of FIG. 1, and FIG. 12B depicts a cross-sectional view, along section line B of FIG. 1, of a process of forming a top source/drain contact and a bottom source/drain contact, in accordance with an embodiment of the invention.

### DETAILED DESCRIPTION

Embodiments of the present invention recognize that when a device includes there are stacked field-effect transistors (FETs), including an upper FET (also referred to as a second transistor or a second FET) and lower FET (also referred to as a first transistor or a first FET), shorting issues may occur between the gate and source/drain contact of the bottom device. Embodiments of the present invention recognize that when creating a bottom source/drain contact in a device that uses traditional methods to include a poly open chemical-mechanical planarization (CMP) (POC) layer in between the upper and the lower FET, a reactive-ion etching (RIE) process may be used that includes, for example, a self aligned contact (SAC) oxide etch, followed by a SiN open, followed by another SAC oxide etch, followed by another SiN open. Embodiments of the present invention recognize that inserting an SiN etch between SAC oxide etches leads to gate spacer and gate cap loss, which may cause a short along the lower gate contact.

Embodiments of the present invention describe an approach for fabricating a semiconductor device, the approach including forming a stacked FET bottom and bottom source/drain region. Embodiments of the present invention further describe forming a first SiN liner and oxide interlayer dielectric (ILD) region. Embodiments of the present invention further describe forming a top source/drain region. Embodiments of the present invention further describe recessing the oxide ILD and exposing the first SiN liner such that a top surface of the bottom source/drain region is exposed. Embodiments of the present invention further describe forming a second SiN liner and a second oxide ILD. Embodiments of the present invention further describe removing a dummy gate, performing a SiGe release, forming a replacement metal gate, and forming a sacrificial cap. Embodiments of the present invention further describe forming a bottom source/drain contact using, for example, oxide RIE landing over the second SiN liner. Embodiments of the present invention further describe opening the second SiN liner. Embodiments of the present invention further describe forming the bottom contact metallization.

Embodiments of the present invention describe a resulting semiconductor structure that includes at least one transistor stacked over another transistor. Embodiments of the present invention further describe that there is a dielectric liner between a top ILD layer and a bottom ILD layer. Embodiments of the present invention further describe that the dielectric liner is below a top surface of a bottom source/drain region.

In some embodiments, a top ILD layer and a bottom ILD layer are made of oxide. In some embodiments the dielectric liner is made of SiN. In some embodiments, the dielectric liner wraps around the top source/drain region, covering a bottom surface of the top source/drain region. In some embodiments, a gate spacer above the dielectric liner is L-shaped. In some embodiments, the bottom source/drain contact lands over the bottom source/drain region by etching through the top ILD and dielectric liner, without etching into the bottom ILD.

According to an aspect of the invention, there is provided a semiconductor structure that includes a first transistor having a first source/drain region, a second transistor, where the second transistor is stacked above the first transistor, and a first dielectric liner between a first ILD and a second ILD, where the first dielectric liner is below a top surface of the first source/drain region. This can serve to prevent a short when forming a contact to the first source/drain region.

In embodiments, the first ILD and the second ILD are each composed of an oxide. This can serve to allow for a SAC oxide etch to form a trench through each ILD when forming source/drain contacts.

In embodiments, the first dielectric liner is composed of silicon nitride (SIN). This can serve to have the first dielectric liner be of a different material than the ILD.

In embodiments, the second transistor has a second source/drain region, and there is further provided a second dielectric liner, where the second dielectric liner surrounds the second source/drain region such that a bottom surface of the second source/drain region is covered. This can serve to protect the second source/drain region.

In embodiments, there is further provided a gate spacer above the first dielectric liner, where the gate spacer has an L-shape. This can serve to protect the replacement gate.

In embodiments, there is further provided a first source/drain contact contacting the first source/drain region, where the first source/drain contact passes through the first ILD and the first dielectric liner. This can serve to provide a contact to the bottom source/drain region.

In embodiments, there is further provided a second source/drain contact contacting the second source/drain region, where the second source/drain contact passes through the first ILD and the second dielectric liner. This can serve to provide a contact to the top source/drain region.

In embodiments, the first source/drain contact passes between a first gate region and a second gate region. This can serve to utilize the first gate region and the second gate region to create a self-aligned trench used for the formation of the first source/drain contact.

In embodiments, the first source/drain region is larger than the second source/drain region. This can serve to allow a contact to be placed vertically above the bottom source/drain region without interfering with the top source/drain region.

According to an aspect of the invention, there is provided a bottom source/drain region, a top source/drain region, and a dielectric liner between a bottom ILD and a top ILD, where the dielectric liner is below a top surface of the bottom source/drain region. This can serve to prevent a short when forming a contact to the first source/drain region.

In embodiments, the bottom ILD and the top ILD are each composed of an oxide. This can serve to allow for a SAC oxide etch to form a trench through each ILD when forming source/drain contacts.

In embodiments, the dielectric liner is composed of silicon nitride (SiN). This can serve to have the first dielectric liner be of a different material than the ILD.

In embodiments, there is further provided a second dielectric liner wrapping around the top source/drain region such that sidewalls and a bottom surface of the top source/drain region are in contact with the second dielectric liner. This can serve to protect the second source/drain region.

In embodiments, there is further provided a gate spacer above the dielectric liner, where the gate spacer has an L-shape. This can serve to protect the replacement gate.

In embodiments, there is further provided a bottom source/drain contact contacting the bottom source/drain region, where the bottom source/drain contact passes through the top ILD and the dielectric liner. This can serve to provide a contact to the bottom source/drain region.

In embodiments, there is further provided a top source/drain contact contacting the top source/drain region, where the top source/drain contact passes through the top ILD and the second dielectric liner. This can serve to provide a contact to the top source/drain region.

In embodiments, the bottom source/drain contact passes between two gate regions. This can serve to utilize the two gate regions to create a self-aligned trench used for the formation of the first source/drain contact.

In embodiments, the bottom source/drain region is larger than the top source/drain region. This can serve to allow a contact to be placed vertically above the bottom source/drain region without interfering with the top source/drain region.

According to an aspect of the invention, there is provided a method of forming a semiconductor structure that includes forming a first source/drain region for a FET. The method may also include forming a dielectric liner. The method may also include forming an ILD. The method may also include forming a second source/drain region for a second FET. The method may also include recessing the ILD and the dielectric liner to expose a top surface of the first source/drain region. The method may also include forming a second dielectric liner. The method may also include forming a second ILD. The method may also include forming a trench through the second ILD above the first source/drain region. The method may also include removing an exposed portion of the dielectric liner within the trench. The method may also include forming a first contact in the trench. This can serve to prevent a short when subsequently forming a contact to the first source/drain region.

In embodiments, the method may also include forming a second trench through the second ILD above the second source/drain region. The method may also include removing an exposed portion of the second dielectric liner within the second trench. The method may also include forming a second contact in the second trench. This can serve to prevent a short when forming a contact to the first source/drain region.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Each reference number may refer to an item individually or collectively as a group. For example, bottom source/drain region 240 may refer to a single bottom source drain region 240 or multiple bottom source/drain regions 240.

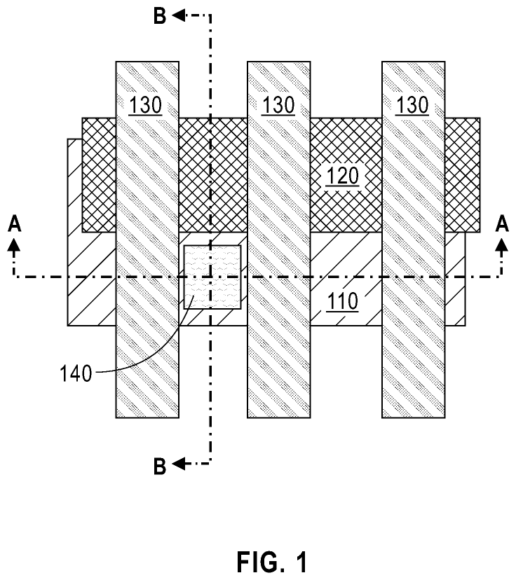

FIG. 1 is a simplified depiction of the device and that is provided primarily to establish a frame of reference for the presence of the cross-sectional views of the other Figures. Accordingly, many objects and features that are present in the cross-sectional views are not depicted in FIG. 1.

The present invention will now be described in detail with reference to the Figures.

FIG. 1 depicts a top-down view of a device during the method of forming the device. FIG. 1 depicts the general arrangement of bottom active device area (RX) 110, top RX 120, gates 130, and bottom source/drain contact 140 of each stacked FET structure.

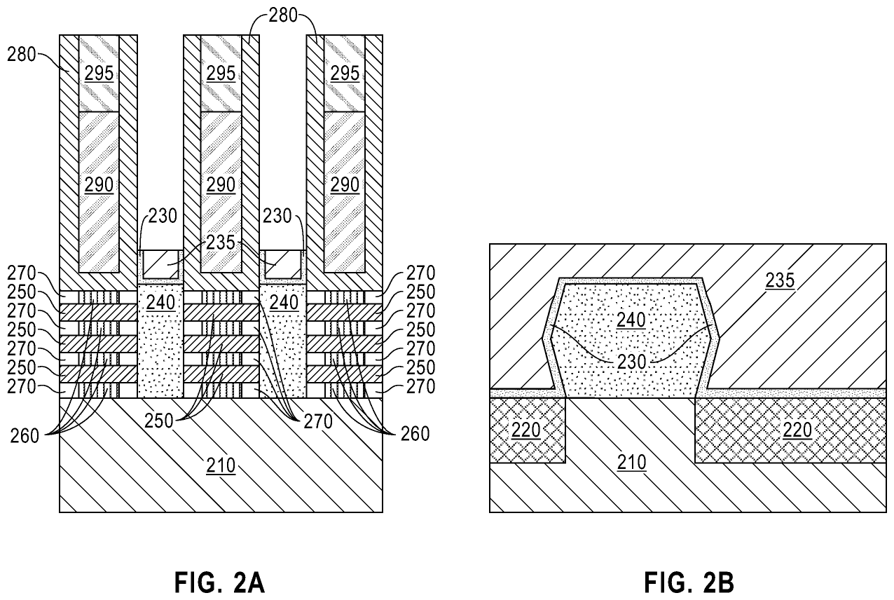

FIG. 2A depicts a cross-sectional view along section line A of FIG. 1 and FIG. 2B depicts a cross-sectional view along section line B of FIG. 1, in accordance with an embodiment of the present invention. More particularly, FIGS. 2A-2B depict the device during the method of forming the device subsequent to steps such as nanosheet stack patterning, shallow trench isolation (STI) formation, dummy gate formation, high germanium containing silicon germanium (SiGe) layer removal, middle dielectric isolation (MDI) formation, low-germanium containing nanosheet recessing, inner spacer formation, bottom source/drain formation, POC liner deposition, oxide fill, oxide recess, and exposed POC liner removal.

The semiconductor structure of FIGS. 2A-2B includes a semiconductor substrate upon which embodiments of the invention can be fabricated.

Semiconductor substrate 210 may be composed of a silicon containing material. Silicon containing materials include, but are not limited to, silicon, single crystal silicon, polycrystalline silicon, SiGe, single crystal SiGe, polycrystalline SiGe, or silicon doped with carbon (C), amorphous silicon, and combinations and multi-layers thereof. Semiconductor substrate 210 can also be composed of other semiconductor materials, such as germanium (Ge), and compound semiconductor substrates, such as type III/V semiconductor substrates, e.g., gallium arsenide (GaAs). In general, semiconductor substrate 210 is a smooth surface substrate. In some embodiments (not shown), semiconductor substrate 210 can be a partially processed complementary metal-oxide semiconductor (CMOS) integrated wafer with transistors and wiring levels or gate electrodes embedded beneath the surface.

In some embodiments, a buried oxide layer (not depicted) is present above semiconductor substrate 210. The buried oxide layer acts as an electrical insulator.

Stacked FETs are depicted in FIGS. 2A-2B and may generally be formed as described herein.

In the depicted embodiment, a semiconductor material stack (sacrificial semiconductor material layer 260, semiconductor channel material layer 250) is formed upon semiconductor substrate 210. The semiconductor material stack includes vertically aligned alternating layers of sacrificial semiconductor material layer 260 and semiconductor channel material layer 250. The semiconductor material stack is sequentially formed upon semiconductor substrate 210. As mentioned above, the semiconductor material stack includes sacrificial semiconductor material layers 260 and semiconductor channel material layers 250, which alternate one atop the other. In FIGS. 2A-2B, and only by way of one example, the semiconductor material stack includes four layers of sacrificial semiconductor material layer 260 and three layers of semiconductor channel material layer 250. In some embodiments, an additional middle sacrificial layer can be formed between the top and bottom FET, which will later be removed and replaced with a dielectric spacer material layer 280, also called middle dielectric isolation (MDI). The semiconductor material stacks that can be employed in embodiments of the present invention are not limited to the specific embodiment illustrated in FIGS. 2A-2B. Instead, the semiconductor material stack can include any number of sacrificial semiconductor material layers 260 and semiconductor channel material layers 250. The semiconductor material stack is used to provide a gate-all-around device that includes vertically stacked semiconductor channel material nanosheets for a p-channel field-effect transistor (pFET) or n-channel field-effect transistor (nFET) device. It should be noted that while the depicted embodiment uses a nanosheet device for the bottom device, the bottom device can be any kind of non-vertical or horizontal device, such as, for example, fin field-effect transistor (FinFET), planar FET, nanowire, or extremely-thin silicon-on-insulator (ETSOI).

Each sacrificial semiconductor material layer is composed of a first semiconductor material which differs in composition from at least an upper portion of semiconductor substrate 210. In one embodiment, each sacrificial semiconductor material layer is composed of SiGe. In such an embodiment, the silicon germanium alloy content of the sacrificial semiconductor material layer may have a germanium content that is less than fifty atomic percent germanium. In one example, the SiGe alloy that makes up the sacrificial semiconductor material layer 260 has a germanium content from twenty atomic percent germanium to forty atomic percent germanium. The first semiconductor material, for each sacrificial semiconductor material layer 260, can be formed utilizing an epitaxial growth or deposition process.

Each semiconductor channel material layer 250 is composed of a second semiconductor material that has a different etch rate than the first semiconductor material of the sacrificial semiconductor material layers. The second semiconductor material of each semiconductor channel material layer 250 may be the same as, or different than, the semiconductor material of, at least, the upper portion of semiconductor substrate 210. The second semiconductor material can be, for example, silicon. The second semiconductor material can be a SiGe alloy having a germanium content of twenty to fifty atomic percent germanium and the first semiconductor material is different than the second semiconductor material.

In one example, at least the upper portion of semiconductor substrate 210 and each semiconductor channel material layer 250 is composed of Si or a III-V compound semiconductor, while each sacrificial semiconductor material layer is composed of a SiGe alloy. The second semiconductor material, for each semiconductor channel material layer 250, can be formed utilizing an epitaxial growth or deposition process. The middle sacrificial layer (not shown) can be a different epitaxial growth layer, which is different than sacrificial semiconductor material layer 260 or semiconductor channel material layer 250 (e.g., SiGe with a higher Ge %, such as, for example, greater than 55%).

Semiconductor material stack (sacrificial semiconductor material layer 260, semiconductor channel material layer 250) can be formed by sequential epitaxial growth of alternating layers of the first semiconductor material and the second semiconductor material. Following epitaxial growth of the topmost layer of the semiconductor material stack (sacrificial semiconductor material layer 260, semiconductor channel material layer 250) a patterning process may be used to provide the semiconductor material stack (sacrificial semiconductor material layer 260, semiconductor channel material layer 250). Patterning may be achieved by lithography and etching as is well known to those skilled in the art.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. The epitaxial growth the first and second semiconductor materials that provide the sacrificial semiconductor material layers 260 and the semiconductor channel material layers 250, respectively, can be performed utilizing any well-known precursor gas or gas mixture. Carrier gases like hydrogen, nitrogen, helium and argon can be used.

The sacrificial semiconductor material layers 260 that constitutes the semiconductor material stack may have a thickness from five nm to twelve nm, while the semiconductor channel material layers 250 that constitute the semiconductor material stack may have a thickness from six nm to twelve nm. Each sacrificial semiconductor material layer 260 may have a thickness that is the same as, or different from, a thickness of each semiconductor channel material layer 250. In an embodiment, each sacrificial semiconductor material layer 260 has an identical thickness. In an embodiment, each semiconductor channel material layer 250 has an identical thickness.

Following epitaxial growth of the topmost layer of the semiconductor material stack (sacrificial semiconductor material layer 260, semiconductor channel material layer 250), a patterning process may be used to provide the semiconductor material stack. Patterning may be achieved by lithography and etching as is well known to those skilled in the art.

Shallow trench isolation (STI) layer 220 may be formed by patterning a hardmask layer (not shown) using lithography and etching such that top surfaces of portions of semiconductor substrate 210 are exposed corresponding to locations where trenches for STI layer 220 are desired. Accordingly, the hardmask layer is patterned such that semiconductor substrate 210 is exposed at desired trench locations for STI layer 220.

Physically exposed portions of semiconductor substrate 210 are removed. The removing of portions of semiconductor substrate 210 can be performed utilizing an anisotropic etching process such as, for example, reactive ion etching (RIE). Portions of semiconductor substrate 210 remain beneath the hardmask.

A sacrificial gate structure and dielectric spacer material layer 280 (also referred to as a gate spacer) may be formed. Each sacrificial gate structure is located on a first side and a second side of the semiconductor material stack (sacrificial semiconductor material layer 260, semiconductor channel material layer 250) and spans across a topmost surface of a portion of the semiconductor material stack (sacrificial semiconductor material layer 260, semiconductor channel material layer 250). Each sacrificial gate structure thus straddles over a portion of the semiconductor material stack (sacrificial semiconductor material layer 260, semiconductor channel material layer 250). The dielectric spacer material layer 280 is present on sidewalls of each sacrificial gate structure and, for sake of simplicity, is depicted as including the MDI layer that is between sacrificial gate structure and the semiconductor material stack (sacrificial semiconductor material layer 260, semiconductor channel material layer 250); the dielectric spacer material layer 280 thus also straddles over the semiconductor material stack (sacrificial semiconductor material layer 260, semiconductor channel material layer 250).

Each sacrificial gate structure may include a single sacrificial material portion or a stack of two or more sacrificial material portions (i.e., at least one sacrificial material portion). In one embodiment, the at least one sacrificial material portion comprises, from bottom to top, a sacrificial gate dielectric portion (e.g., MDI), a sacrificial gate portion 290 and a sacrificial dielectric cap portion 295. In some embodiments, the sacrificial gate dielectric portion (e.g., MDI) and/or the sacrificial dielectric cap portion 295 can be omitted and only a sacrificial gate portion 290 is formed. The at least one sacrificial material portion can be formed by forming a blanket layer (or layers) of a material (or various materials) and then patterning the material (or various materials) by lithography and an etch. In one embodiment, the at least one sacrificial material portion can be formed by first depositing a blanket layer of a sacrificial gate dielectric material (e.g., MDI). The sacrificial gate dielectric material (e.g., MDI) can be an oxide, nitride, and/or oxynitride. In one example, the sacrificial gate dielectric material (e.g., MDI) can be a high-k material having a dielectric constant greater than silicon dioxide. In some embodiments, a multilayered dielectric structure comprising different dielectric materials, e.g., silicon dioxide, and a high-K dielectric can be formed and used as the sacrificial gate portion 290. The sacrificial gate dielectric material (e.g., MDI) can be formed by any deposition technique including, for example, chemical vapor deposition (CVD), plasma enhanced chemical vapor deposition (PECVD), physical vapor deposition (PVD), sputtering, or atomic layer deposition (ALD).

After forming the blanket layer of sacrificial gate dielectric material (e.g., MDI), a blanket layer of a sacrificial gate material can be formed on the blanket layer of sacrificial gate dielectric material. The sacrificial gate material can include any material including, for example, polysilicon, amorphous silicon, an elemental metal (e.g., tungsten, titanium, tantalum, aluminum, nickel, ruthenium, palladium, and platinum), an alloy of at least two elemental metals, or multilayered combinations thereof. The sacrificial gate material can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

After forming the blanket layer of sacrificial gate material, a blanket layer of a sacrificial gate cap material can be formed. The sacrificial gate cap material may include a hardmask material such as, for example, silicon dioxide and/or silicon nitride. The sacrificial gate cap material can be formed by any suitable deposition process such as, for example, chemical vapor deposition (CVD) or plasma enhanced chemical vapor deposition (PECVD).

After providing the above mentioned sacrificial material stack (or any subset of the sacrificial materials), lithography and etching can be used to pattern the sacrificial material stack (or any subset of the sacrificial materials) and to provide the at least one sacrificial gate structure. The remaining portions of the sacrificial gate dielectric material constitute a sacrificial gate dielectric portion (e.g., MDI), the remaining portions of the sacrificial gate material constitute a sacrificial gate portion 290, and the remaining portions of the sacrificial dielectric cap material constitute a sacrificial dielectric cap portion 295.

After providing the sacrificial gate structure, the exposed middle sacrificial layer (e.g., high Ge % SiGe layer) is selectively removed respective to semiconductor channel material layer 250 and sacrificial semiconductor material layers 260, followed by filling the cavities with MDI (i.e., portion of dielectric spacer material layer 280 below sacrificial gate portion 290. After, the dielectric spacer material layer (i.e., remaining portion of dielectric spacer material layer 280, on sidewalls of sacrificial gate portion 290 and dielectric cap portion 295) can be formed on exposed surfaces of each sacrificial gate structure. The dielectric spacer material layer can be formed by first providing a dielectric spacer material and then etching the dielectric spacer material. One example of MDI, and a dielectric spacer material (i.e., dielectric spacer material layer 280) that may be employed in the present application is silicon nitride. In general, the MDI and dielectric spacer material layer (i.e., dielectric spacer material layer 280) comprises any dielectric spacer material, including, for example, a dielectric nitride, dielectric oxide, and/or dielectric oxynitride. More specifically, the dielectric spacer material layer may be, for example, SiBCN, SiBN, SiOCN, SION, SiCO, or SiC. In one example, the dielectric spacer material is composed of a dielectric material such as SiO₂.

The dielectric spacer material that provides the dielectric spacer material layer may be provided by a deposition process including, for example, ALD, chemical vapor deposition (CVD), plasma enhanced chemical vapor deposition (PECVD), or physical vapor deposition (PVD). The etch used to provide the dielectric spacer material layer may comprise a dry etching process such as, for example, reactive ion etching.

Recesses may be formed within the semiconductor material stack, creating the formation of nanosheet stacks of alternating nanosheets of sacrificial semiconductor material layers 260 and semiconductor channel material layers 250 that are under at least one sacrificial gate structure and dielectric spacer material layer.

The nanosheet stack is formed by removing physically exposed portions of the semiconductor material stack (sacrificial semiconductor material layer 260, semiconductor channel material layer 250) that are not protected by the least one sacrificial gate structure and the dielectric spacer material layer. In general, each recess may include the eventual location of bottom source/drain region 240 (also referred to as the first source/drain region), for the semiconductor device.

The removing of the portions of the semiconductor material stack (sacrificial semiconductor material layer 260, semiconductor channel material layer 250) not covered by the least one sacrificial gate structure and the dielectric spacer material layer can be performed utilizing an anisotropic etching process such as, for example, reactive ion etching (RIE). Portions of the semiconductor material stack (sacrificial semiconductor material layer 260, semiconductor channel material layer 250) remain beneath at least one sacrificial gate structure and the dielectric spacer material layer. The remaining portion of the semiconductor material stack that is present beneath the at least one sacrificial gate structure and the dielectric spacer material layer is referred to as a nanosheet stack.

Each nanosheet stack includes alternating nanosheets of remaining portions of each sacrificial semiconductor material layer 260 and remaining portions of each semiconductor channel material layer 250. The nanosheet stack includes alternating nanosheets of remaining portions of each of sacrificial semiconductor material layer 260 and semiconductor channel material layer 250. Each nanosheet (i.e., sacrificial semiconductor material layer 260 or semiconductor channel material layer 250) that constitutes the nanosheet stack has a thickness as mentioned above for the individual sacrificial semiconductor material layers 260 and semiconductor channel material layers 250, and a width from 30 nm to 200 nm. In some embodiments, the sidewalls of each sacrificial semiconductor material layer 260 are vertically aligned to sidewalls of each semiconductor channel material layer 250, and the vertically aligned sidewalls of the nanosheet stack are vertically aligned to an outmost sidewall of dielectric spacer material layer.

The sacrificial semiconductor material layer 260 is recessed and inner spacer 270 is formed. Each recessed sacrificial semiconductor material layer 260 has a width that is less than the original width of each sacrificial semiconductor material layer 260. The recessing of each sacrificial semiconductor material layer 260 provides a gap between each neighboring pair of semiconductor channel material layer 250 within a given nanosheet stack. The recessing of each sacrificial semiconductor material layer 260 may be performed utilizing a lateral etching process that is selective in removing physically exposed end portions of each sacrificial semiconductor material layer 260 relative to each semiconductor channel material layer 250.

The additional dielectric spacer material that is added can be compositionally the same as the dielectric spacer material layer mentioned above. In one example, the additional dielectric spacer material and the dielectric spacer material layer are both composed of silicon nitride. The inner spacer 270 is formed by a conformal dielectric liner deposition followed by isotropic etching back the deposited liner.

Bottom source/drain region 240 is formed by epitaxial growth of a semiconductor material on physically exposed top surfaces of semiconductor substrate 210 and physically exposed sidewalls of each semiconductor channel material layer 250 below the MDI portion of dielectric spacer material layer 280. The bottom source/drain region 240 has a bottommost surface that directly contacts a topmost surface of semiconductor substrate 210.

Each bottom source/drain region 240 includes a semiconductor material and a dopant. The semiconductor material that provides each bottom source/drain region 240 can be selected from one of the semiconductor materials mentioned above for the semiconductor substrate 210. In some embodiments, the semiconductor material that provides each bottom source/drain region 240 may comprise a same semiconductor material as that which provides semiconductor channel material layer 250. In other embodiments, the semiconductor material that provides each bottom source/drain region 240 may comprise a different semiconductor material than that which provides semiconductor channel material layer 250. For example, the semiconductor material that provides each bottom source/drain region 240 may comprise a silicon germanium alloy, while semiconductor channel material layer 250 may comprise silicon.

The dopant that is present in each bottom source/drain region 240 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic, and phosphorous. In one embodiment, the dopant that can be present in each bottom source/drain region 240 can be introduced into the precursor gas that provides each bottom source/drain region 240. In another embodiment, the dopant can be introduced into an intrinsic semiconductor layer by utilizing one of ion implantation or gas phase doping. In one example, each bottom source/drain region 240 comprises a silicon germanium alloy that is doped with a p-type dopant such as, for example, boron. As mentioned above, each bottom source/drain region 240 is formed by an epitaxial growth (or deposition) process, as is defined above.

POC liner 230 (also referred to as a dielectric liner or a first dielectric liner) formed on each of bottom source/drain region 240 and STI layer 220, as well as along sidewalls of dielectric spacer material layer 280. POC liner 230 may be a dielectric liner of a dielectric material such as, for example, nitride, silicon nitride, or other low-materials. POC liner 230 can be formed by any deposition technique including, for example, chemical vapor deposition (CVD), plasma enhanced chemical vapor deposition (PECVD), physical vapor deposition (PVD), sputtering, or atomic layer deposition (ALD).

ILD material 235 (also referred to as the second ILD or the bottom ILD) is formed on each POC liner 230. ILD material 235 may be composed of silicon dioxide, undoped silicate glass (USG), fluorosilicate glass (FSG), borophosphosilicate glass (BPSG), a spin-on low-K dielectric layer, a chemical vapor deposition (CVD) low-K dielectric layer or any combination thereof. The term “low-K” as used throughout the present application denotes a dielectric material that has a dielectric constant of less than silicon dioxide. In another embodiment, a self-planarizing material such as a spin-on glass (SOG) or a spin-on low-K dielectric material such as SiLK™ can be used as ILD material 235.

In one embodiment, ILD material 235 can be formed utilizing a deposition process including, for example, chemical vapor deposition (CVD), plasma enhanced chemical vapor deposition (PECVD), evaporation or spin-on coating. In some embodiments, a planarization an etch back process, such as oxide etching, follows the deposition of the dielectric material that provides ILD material 235, such that ILD material 235 is selectively removed, and a location desired for top source/drain region 310 may be exposed.

Exposed portions of POC liner 230 are subsequently removed using an etching process such as for example, a wet etching process, a dry etching process, CMP, or any other removal or thinning process capable of selectively removing exposed portions of POC liner 230, stopping at a top surface of ILD material 235.

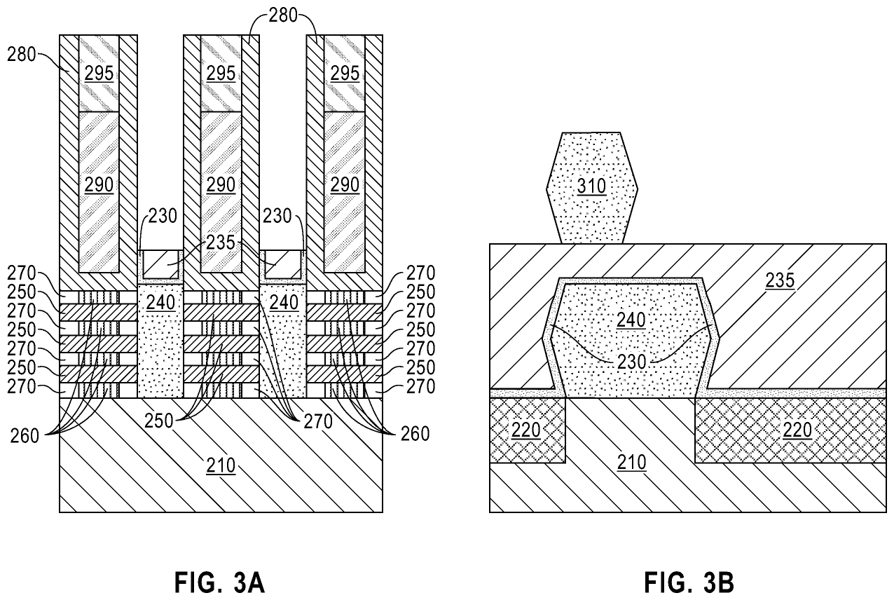

FIG. 3A depicts a cross-sectional view along section line A of FIG. 1 and FIG. 3B depicts a cross-sectional view along section line B of FIG. 1, in accordance with an embodiment of the present invention. FIGS. 3A-3B depict the formation of top source/drain region 310 (also referred to as the second source/drain region).

While not depicted in detail, top RX 120 (see FIG. 1) may be another FET, similar or different to that described with reference to the lower FET in FIGS. 2A-2B. In general, the top RX includes a top source/drain region 310 that has a horizontal width less than that of bottom source/drain region 240, such that subsequent contact formation to source/drain region 240 is possible from above.

The top source/drain region 310 is formed by epitaxial growth of a semiconductor material on physically exposed sidewalls of each semiconductor channel material layer (not depicted) of the top FET. In the depicted embodiment, the semiconductor material that provides the top source/drain region 310 grows laterally out from the sidewalls of each semiconductor channel material layer (not depicted) of the top FET. The top source/drain region 310 has a bottommost surface that directly contacts a topmost surface of the ILD material 235 that is present atop the bottom source/drain region 240.

Each top source/drain region 310 includes a semiconductor material and a dopant. The semiconductor material that provides each top source/drain region 310 can be selected from one of the semiconductor materials mentioned above for the semiconductor substrate 210. In some embodiments, the semiconductor material that provides each top source/drain region 310 may comprise a same semiconductor material as that which provides semiconductor channel material layer (not depicted) of the top FET. In other embodiments, the semiconductor material that provides each top source/drain region 310 may comprise a different semiconductor material than that which provides the semiconductor channel material layer (not shown) of the top FET. For example, the semiconductor material that provides each top source/drain region 310 may comprise a silicon germanium alloy, while the semiconductor channel material layer of the top FET may comprise silicon.

The dopant that is present in each top source/drain region 310 can be either a p-type dopant or an n-type dopant. In one embodiment, the dopant that can be present in each top source/drain region 310 can be introduced into the precursor gas that provides each top source/drain region 310. In another embodiment, the dopant can be introduced into an intrinsic semiconductor layer by utilizing one of ion implantation or gas phase doping. In one example, each top source/drain region 310 comprises a silicon germanium alloy that is doped with a p-type dopant such as, for example, boron. As mentioned above, each top source/drain region 310 is formed by an epitaxial growth (or deposition) process, as is defined above.

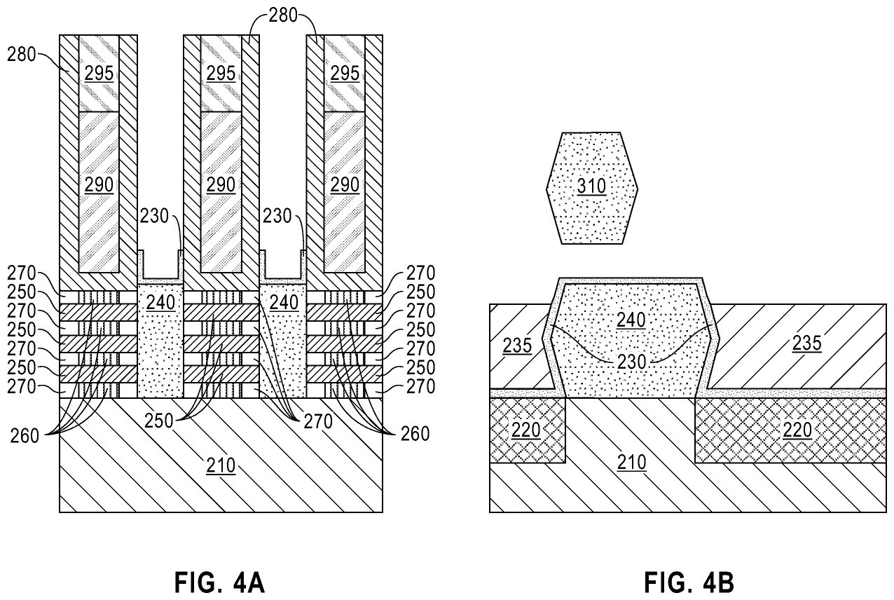

FIG. 4A depicts a cross-sectional view along section line A of FIG. 1 and FIG. 4B depicts a cross-sectional view along section line B of FIG. 1, in accordance with an embodiment of the present invention. FIGS. 4A-4B depict the removal of additional ILD material 235.

In some embodiments, a planarization an etch back process, such as oxide etching, is utilized to selectively remove exposed portions of ILD material 235, such that POC liner 230 on bottom source/drain region 240 is exposed, resulting in a top surface of bottom source/drain region 240 being above a top surface of ILD material 235.

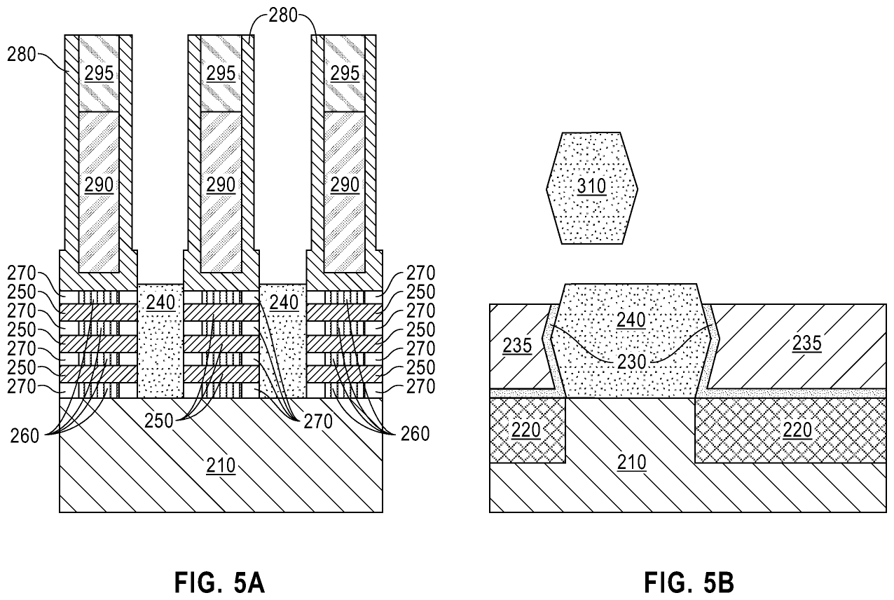

FIG. 5A depicts a cross-sectional view along section line A of FIG. 1 and FIG. 5B depicts a cross-sectional view along section line B of FIG. 1, in accordance with an embodiment of the present invention. FIGS. 5A-5B depict the removal of exposed portions of POC liner 230.

Exposed portions of POC liner 230 are subsequently removed using an etching process such as for example, a wet etching process, a dry etching process, CMP, or any other removal or thinning process capable of selectively removing exposed portions of POC liner 230, stopping at a top surface of ILD material 235.

The removal of the exposed portions of POC liner 230 exposes at least a top surface of bottom source/drain region 240.

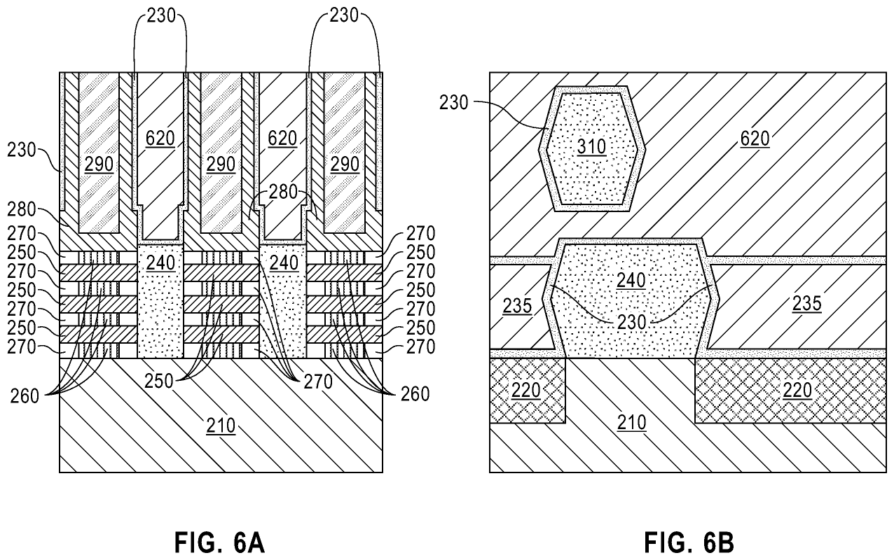

FIG. 6A depicts a cross-sectional view along section line A of FIG. 1 and FIG. 6B depicts a cross-sectional view along section line B of FIG. 1, in accordance with an embodiment of the present invention. FIGS. 6A-6B depict the formation of additional POC liner material and ILD material 620 (also referred to as the first ILD, the top ILD, or the ILD).

Additional POC liner 230 material (also referred to as the second dielectric liner, when referring to the portion of POC liner 230 that surrounds top source/drain region 310) is formed on exposed portions of each of top source/drain region 310, bottom source/drain region 240, as well as along sidewalls of dielectric spacer material layer 280. POC liner 230 may be a dielectric liner of a dielectric material such as, for example, nitride, silicon nitride, or other low-K materials. POC liner 230 can be formed by any deposition technique including, for example, chemical vapor deposition (CVD), plasma enhanced chemical vapor deposition (PECVD), physical vapor deposition (PVD), sputtering, or atomic layer deposition (ALD).

Additional ILD material 620 is formed above each bottom source/drain region 240 and surrounding each top source/drain region 310. ILD material 620 may be composed of silicon dioxide, undoped silicate glass (USG), fluorosilicate glass (FSG), borophosphosilicate glass (BPSG), a spin-on low-K dielectric layer, a chemical vapor deposition (CVD) low-K dielectric layer or any combination thereof. The term “low-K” as used throughout the present application denotes a dielectric material that has a dielectric constant of less than silicon dioxide. In another embodiment, a self-planarizing material such as a spin-on glass (SOG) or a spin-on low-K dielectric material such as SiLK™ can be used as ILD material 620. The use of a self-planarizing dielectric material as ILD material 620 may avoid the need to perform a subsequent planarizing step.

In one embodiment, ILD material 620 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as ILD material 620, a planarization process or an etch back process follows the deposition of the dielectric material that provides ILD material 620, such that a top surface of sacrificial gate portion 290 is revealed. As is shown in FIGS. 6A-6B, ILD material 620 that is present atop each top source/drain region 310 has a topmost surface that is coplanar to a topmost surface of sacrificial gate portion 290. In some embodiments, subsequent to a steam anneal, a poly open chemical-mechanical planarization process is used.

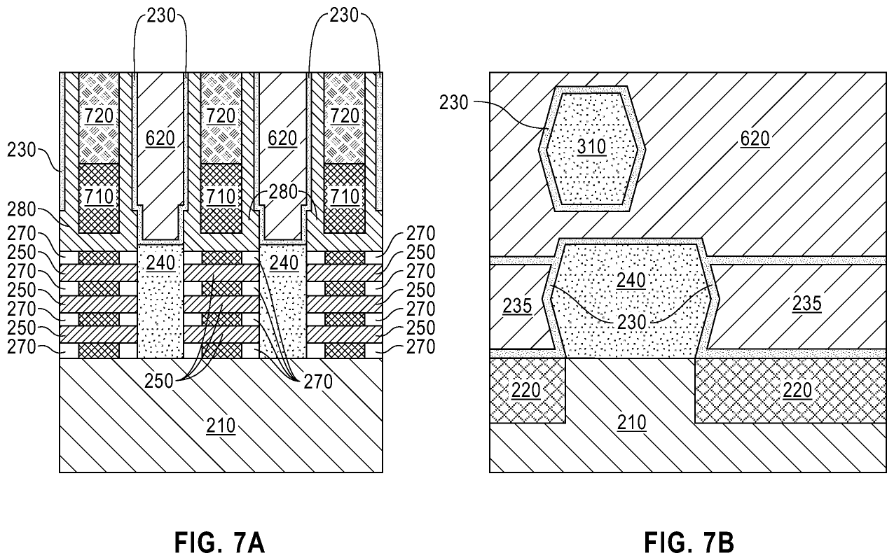

FIG. 7A depicts a cross-sectional view along section line A of FIG. 1 and FIG. 7B depicts a cross-sectional view along section line B of FIG. 1, in accordance with an embodiment of the present invention. FIGS. 7A-7B depict the removal of sacrificial gate portion 290 and sacrificial semiconductor material layer 260, and the formation of replacement gate 710 and sacrificial cap 720. It should be noted that there may be multiple instances of replacement gate 710, for example, as depicted, there is, from left to right, a first gate region, a second gate region, and a third gate region when referring to the separate instances of replacement gate 710.

Each sacrificial gate structure (i.e., sacrificial gate portion 290) is removed to provide a gate cavity for both the top and bottom FETs.

Next, each semiconductor channel material nanosheet (i.e., semiconductor channel material layer 250) of both the top and bottoms FETs is suspended by selectively etching each recessed sacrificial semiconductor material nanosheet (i.e., sacrificial semiconductor material layer 260) relative to each semiconductor channel material nanosheet (i.e., semiconductor channel material layer 250).

Functional gate structures are formed in each gate cavity. For the bottom FET, the functional gate structure surrounds a physically exposed surface of each semiconductor channel material nanosheet (i.e., semiconductor channel material layer 250). For the top FET the functional gate structure surrounds a physically exposed surface of each semiconductor channel material nanosheet (not depicted). By “functional gate structure” it is meant a permanent gate structure used to control output current (i.e., flow of carriers in the channel) of a semiconducting device through electrical or magnetic fields. Collectively, both gate structures are referred to as replacement gate 710 in the Figures.

While not depicted, in some embodiments, a gate dielectric portion may be present that includes a gate dielectric material. Such a gate dielectric portion may be an oxide, nitride, and/or oxynitride. In one example, the gate dielectric portion can be a high-k material having a dielectric constant greater than silicon dioxide. Example high-K dielectrics include, but are not limited to, HfO2, ZrO2, La2O3, Al2O3, TiO2, SrTiO3, LaAlO3, Y2O3, HfOxNy, ZrOxNy, La2OxNy, Al2OxNy, TiOxNy, SrTiOxNy, LaAlOxNy, Y2OxNy, SiON, SiNx, a silicate thereof, and an alloy thereof. Each value of x is independently from 0.5 to 3 and each value of y is independently from 0 to 2. In some embodiments, a multilayered gate dielectric structure comprising different gate dielectric materials, e.g., silicon dioxide, and a high-K gate dielectric, can be formed and used as the gate dielectric portion.

The gate dielectric material used in providing a gate dielectric portion can be formed by any deposition process including, for example, chemical vapor deposition (CVD), plasma enhanced chemical vapor deposition (PECVD), physical vapor deposition (PVD), sputtering, or atomic layer deposition. In one embodiment of the present application, the gate dielectric material used in providing a gate dielectric portion can have a thickness in a range from 1 nm to 10 nm. Other thicknesses that are lesser than, or greater than, the aforementioned thickness range can also be employed for the gate dielectric material that may provide a gate dielectric portion.

Replacement gate 710 includes a gate conductor material and a gate dielectric. The gate conductor material used in providing replacement gate 710 can include any conductive material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride, TiAIC, TIC, TiAl), an elemental metal silicide (e.g., tungsten silicide, nickel silicide, and titanium silicide), or multilayered combinations thereof. In one embodiment, replacement gate 710 may comprise an nFET gate metal. In another embodiment, replacement gate 710 may comprise a pFET gate metal. When multiple gate cavities are formed, it is possible to form a nFET in a first set of the gate cavities and wrapping around some of the semiconductor channel material nanosheet (i.e., semiconductor channel material layer 250) and a pFET in a second set of the gate cavities and wrapping around some of the semiconductor channel material nanosheet (i.e., semiconductor channel material layer 250).

The gate conductor material used in providing replacement gate 710 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes. When a metal silicide is formed, a conventional silicidation process is employed. In one embodiment, the gate conductor material used in providing replacement gate 710 can have a thickness from 5 nm to 200 nm. Other thicknesses that are lesser than, or greater than, the aforementioned thickness range can also be employed for the gate conductor material used in providing replacement gate 710.

A functional gate structure (replacement gate 710) can be formed by providing a functional gate material stack of the gate dielectric material and the gate conductor material. A planarization process may follow the formation of the functional gate material stack.

Sacrificial cap 720 may be formed on exposed surfaces of the functional gate structure (replacement gate 710), in accordance with an embodiment of the invention. In various embodiments of the invention, sacrificial cap 720 comprises any dielectric spacer material, including, for example, a dielectric nitride, dielectric oxide, and/or dielectric oxynitride. In one example, sacrificial cap 720 is composed of a non-conductive low-capacitance dielectric material such as silicon dioxide (SiO₂). It should be appreciated that any other acceptable materials for forming a dielectric spacer can be used in embodiments of the present invention. For example, the process of forming sacrificial cap 720 may include depositing a conformal layer (not shown) of insulating material, such as nitride, over exposed surfaces of the replacement gate 710. Sacrificial cap 720 can be deposited using, for example, chemical vapor deposition (CVD), plasma enhanced chemical vapor deposition (PECVD), or physical vapor deposition (PVD).

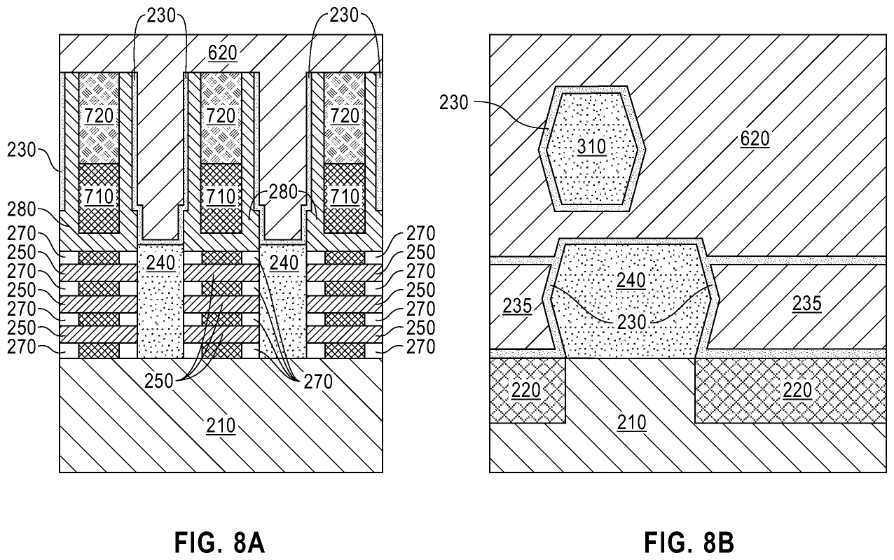

FIG. 8A depicts a cross-sectional view along section line A of FIG. 1 and FIG. 8B depicts a cross-sectional view along section line B of FIG. 1, in accordance with an embodiment of the present invention. FIGS. 8A-8B depict the formation of additional ILD material 620.

Additional ILD material 620 is formed above exposed surfaces of sacrificial cap 720, POC liner 230, dielectric spacer material layer 280, and the already present ILD material 620. ILD material 620 may be composed of silicon dioxide, undoped silicate glass (USG), fluorosilicate glass (FSG), borophosphosilicate glass (BPSG), a spin-on low-K dielectric layer, a chemical vapor deposition (CVD) low-K dielectric layer or any combination thereof. The term “low-K” as used throughout the present application denotes a dielectric material that has a dielectric constant of less than silicon dioxide. In another embodiment, a self-planarizing material such as a spin-on glass (SOG) or a spin-on low-K dielectric material such as SiLK™ can be used as ILD material 620. The use of a self-planarizing dielectric material as ILD material 620 may avoid the need to perform a subsequent planarizing step.

In one embodiment, ILD material 620 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as ILD material 620, a planarization process or an etch back process follows the deposition of the dielectric material that provides ILD material 620. As is shown in FIGS. 8A-8B, ILD material 620 is the top layer and covers the remainder of the device.

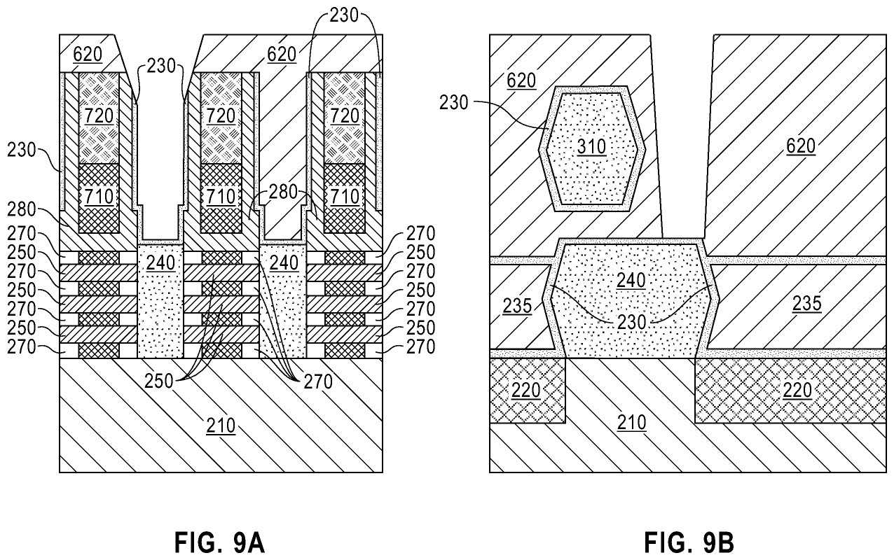

FIG. 9A depicts a cross-sectional view along section line A of FIG. 1 and FIG. 9B depicts a cross-sectional view along section line B of FIG. 1, in accordance with an embodiment of the present invention. FIGS. 9A-9B depict an initial step in the formation of a source/drain contact trench for the bottom source/drain region 240.

A self-aligned cut is etched between two replacement gates 710 and adjacent to, without directly contacting, top source/drain region 310. Being “self-aligned” means that an etch cut, and the resulting filled in material, is resultant from an etch process that is selective to specific areas based on components within the semiconductor structure rather than any lithographically patterned hardmask. In the case of the self-aligned cuts depicted in FIGS. 9A-9B, while a hardmask (not depicted) may be deposited and patterned using lithography and etching to expose the area above bottom source/drain region 240, exposed surfaces of POC liner 230 and dielectric spacer material layer 280 may be not, or less, affected by the etch process used, and the ILD material 620 is affected. Thus, the self-aligned cut will be etched between the replacement gates 710. The self-aligned cut etches through the ILD material 620. The self-aligned cut may taper from a frontside toward a backside. That is, a backside critical dimension is smaller than a more frontside critical dimension.

Subsequent to the formation of the bottom source/drain contact, the hardmask is removed. In general, the process of removing the hardmask involves the use of an etching process such as RIE, laser ablation, or any etch process which can be used to selectively remove a portion of material, such as the hardmask.

Embodiments of the present invention recognize that, gate corner loss can be minimized as the area where the bottom source/drain contact trench is formed does not include a POC layer between the upper and lower FETs, resulting in an SiN etch not being necessary to remove such a layer.

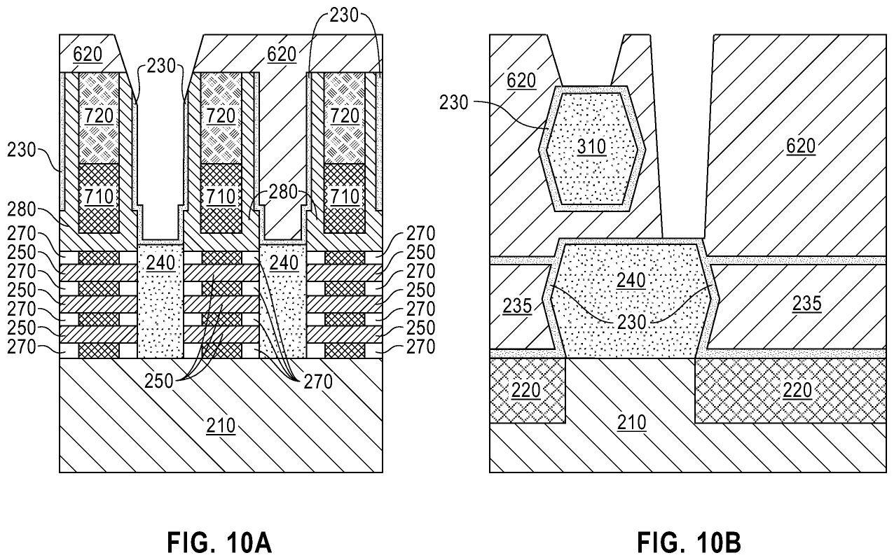

FIG. 10A depicts a cross-sectional view along section line A of FIG. 1 and FIG. 10B depicts a cross-sectional view along section line B of FIG. 1, in accordance with an embodiment of the present invention. FIGS. 10A-10B depict an initial step in the formation of a source/drain contact trench (also referred to as a second trench) for the top source/drain region 310.

A top source/drain contact trench may be formed by lithography and an etching process, such as RIE, laser ablation, or any etch process which can be used to selectively remove a portion of material such as ILD material 620. A hardmask (not shown) may be patterned using photoresist to expose areas of the device where trenches are desired and the hardmask may be utilized during the etching process in the creation of the trenches. The etching process only removes portions of the device not protected by the hardmask and the etching process stops above top source/drain region 310 at POC liner 230.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

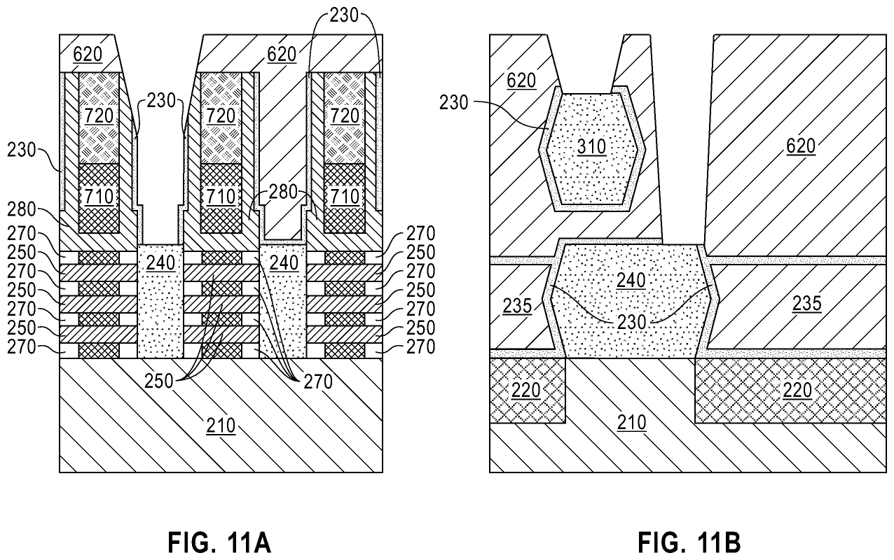

FIG. 11A depicts a cross-sectional view along section line A of FIG. 1 and FIG. 11B depicts a cross-sectional view along section line B of FIG. 1, in accordance with an embodiment of the present invention. FIGS. 11A-11B depict the removal of horizonal portions of POC liner 230, exposing top surfaces of top source/drain region 310 and bottom source/drain region 240.

Exposed portions of POC liner 230 are removed using an etching process such as for example, a wet etching process, a dry etching process, CMP, or any other removal process capable of selectively removing exposed portions of POC liner 230, stopping at a top surface of ILD material 235.

The removal of the exposed portions of POC liner 230 exposes at least a top surface of top source/drain region 310 and bottom source/drain region 240. Embodiments of the present invention recognize that an additional amount of additional gate corner loss may occur but that replacement gate 710 should remain protected.

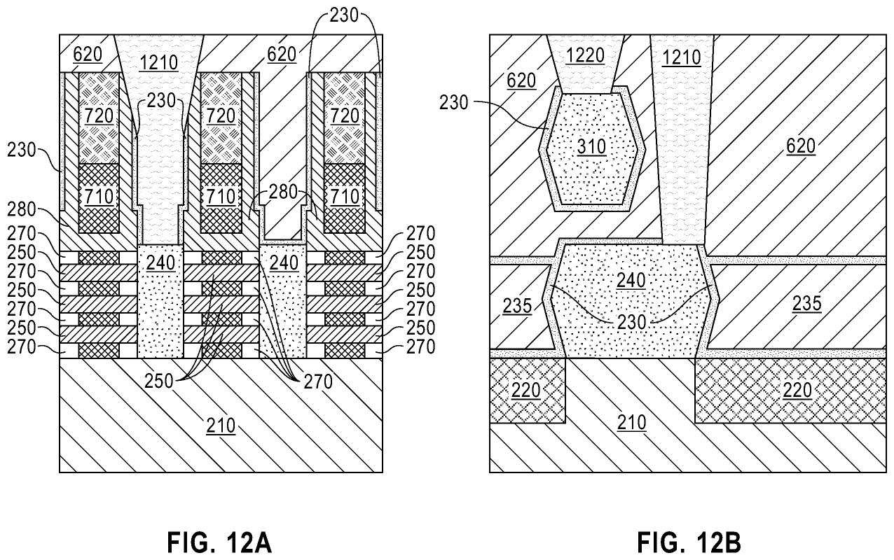

FIG. 12A depicts a cross-sectional view along section line A of FIG. 1 and FIG. 12B depicts a cross-sectional view along section line B of FIG. 1, in accordance with an embodiment of the present invention. FIGS. 12A-12B depict the formation of top source/drain contact 1220 (also referred to as a second source/drain contact or a second contact) and bottom source/drain contact 1210 (also referred to as a first source/drain contact or a first contact).

In general, top source/drain contact 1220 makes contact with top source/drain region 310 and bottom source/drain contact 1210 makes contact with bottom source/drain region 240.

Top source/drain contact 1220 and bottom source/drain contact 1210 may be formed by metal deposition and planarization. The metal layers comprise a silicide liner, such as, for example, Ti, Ni, or NiPt, followed by adhesion metal liner, such as, for example, TiN, and a conductive metal fill, such as, for example, Co, Ru, W, or Cu.

Each of top source/drain contact 1220 and bottom source/drain contact 1210 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

The resulting semiconductor structure includes at least one transistor (e.g., the transistor that includes top source/drain region 310) stacking over another transistor (e.g., the transistor that includes bottom source/drain region 240, semiconductor channel material layer 250, and replacement gate 710). A dielectric liner (POC liner 230) is between the top ILD (ILD material 620) and the bottom ILD (ILD material 235). The dielectric liner (POC liner 230) that is between the top ILD and the bottom ILD is below the top surface of the bottom source/drain region (bottom source/drain region 240).

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first transistor having a first source/drain region;
a second transistor, wherein the second transistor is stacked above the first transistor; and
a first dielectric liner between a first interlayer dielectric (ILD) and a second ILD, wherein the first dielectric liner is below a top surface of the first source/drain region.

2. The semiconductor structure of claim 1, wherein the first ILD and the second ILD are each composed of an oxide.

3. The semiconductor structure of claim 1, wherein the first dielectric liner is composed of silicon nitride (SiN).

4. The semiconductor structure of claim 1, wherein the second transistor has a second source/drain region, further comprising a second dielectric liner, wherein the second dielectric liner surrounds the second source/drain region such that a bottom surface of the second source/drain region is covered.

5. The semiconductor structure of claim 1, further comprising a gate spacer above the first dielectric liner, wherein the gate spacer has an L-shape.

6. The semiconductor structure of claim 1, further comprising a first source/drain contact contacting the first source/drain region, wherein the first source/drain contact passes through the first ILD and the first dielectric liner.

7. The semiconductor structure of claim 4, further comprising a second source/drain contact contacting the second source/drain region, wherein the second source/drain contact passes through the first ILD and the second dielectric liner.

8. The semiconductor structure of claim 6, wherein the first source/drain contact passes between a first gate region and a second gate region.

9. The semiconductor structure of claim 4, wherein the first source/drain region is larger than the second source/drain region.

10. A semiconductor structure comprising:
a bottom source/drain region;
a top source/drain region; and
a dielectric liner between a bottom interlayer dielectric (ILD) and a top ILD, wherein the dielectric liner is below a top surface of the bottom source/drain region.

11. The semiconductor structure of claim 10, wherein the bottom ILD and the top ILD are each composed of an oxide.

12. The semiconductor structure of claim 10, wherein the dielectric liner is composed of silicon nitride (SIN).

13. The semiconductor structure of claim 10, further comprising a second dielectric liner wrapping around the top source/drain region such that sidewalls and a bottom surface of the top source/drain region are in contact with the second dielectric liner.

14. The semiconductor structure of claim 10, further comprising a gate spacer above the dielectric liner, wherein the gate spacer has an L-shape.

15. The semiconductor structure of claim 10, further comprising a bottom source/drain contact contacting the bottom source/drain region, wherein the bottom source/drain contact passes through the top ILD and the dielectric liner.

16. The semiconductor structure of claim 10, further comprising a top source/drain contact contacting the top source/drain region, wherein the top source/drain contact passes through the top ILD and the second dielectric liner.

17. The semiconductor structure of claim 15, wherein the bottom source/drain contact passes between two gate regions.

18. The semiconductor structure of claim 10, wherein the bottom source/drain region is larger than the top source/drain region.

19. A method of forming a semiconductor structure, the method comprising:
forming a first source/drain region for a first field effect transistor (FET);
forming a dielectric liner;
forming an interlayer dielectric (ILD);
forming a second source/drain region for a second FET;
recessing the ILD and the dielectric liner to expose a top surface of the first source/drain region;
forming a second dielectric liner;
forming a second ILD;
forming a trench through the second ILD above the first source/drain region;
removing an exposed portion of the dielectric liner within the trench; and
forming a first contact in the trench.

20. The method of claim 19, further comprising:
forming a second trench through the second ILD above the second source/drain region;
removing an exposed portion of the second dielectric liner within the second trench; and
forming a second contact in the second trench.
